(19) United States
(12) Patent Application Publication
(10) Pub. No.: US 2008/0308302 A1
(43) Pub. Date: Dec. 18, 2008

(54) Printed circuit board with anti-oxidation layer

(75) Inventor: Chia-Huang Lin, Tu-Cheng (TW)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION IND. CO., LTD.

(21) Appl. No.: 12/214,178

(22) Filed: Jun. 16, 2008

(30) Foreign Application Priority Data
Jun. 15, 2007 (CN) 200710023280.8

(51) Int. Cl. H05K 1/00

(52) U.S. Cl. 174/250

(57) ABSTRACT

An anti-oxidant printed circuit board includes at least one layer of insulative base board, some circuits on the base board, at least one electric pad and a notch. The electric pad includes an upper surface plated with at least one layer of anti-oxidant metal foil, a lower surface attached to the base board, a connecting portion connected to the circuit and having a first side surface, and a matching portion connected to complementary connector and having a second side surface. The notch is formed on the second side surface and filled with antioxidant.

### BACKGROUND OF THE INVENTION

1. Field of the Invention

The present invention relates to a printed circuit, and more particularly, to a printed circuit board with an anti-oxidizing layer prolongs the service of the printed circuit board.

2. Description of the Prior Art

Printed circuit boards (PCB) are almost used in every electrical devices to fix some electric elements thereon and make these elements electrical connected to each other.

When the PCB is connected to an other complementary connector, the PCB should have some goldfingers to be used as conductors. In a computer, both a video card and an audio card are electrical connected to the main board via the goldfingers.

The goldfingers always comprise a layer of copper foil, a layer of nickel foil and a layer of gold foil. The nickel foil and the gold foil are plated on the copper foil in turn to improve electric capability and wearability of goldfingers. However, the last step of electroplating process is to cut off pilot wires from goldfingers, which will make copper on the section of goldfingers disclosed in air. In other words, PCB with goldfingers which is made by above method is easy to be oxidized to be influenced on appearance and capability.

Hence, in this art, an improved PCB with goldfingers to overcome the above-mentioned disadvantages of the prior art will be described in detail in the following embodiment.

### BRIEF SUMMARY OF THE INVENTION

A primary object, therefore, of the present invention is to provide an anti-oxidant printed circuit board with simple structure.

In order to implement the above object, the anti-oxidant printed circuit board comprises at least one layer of insulative base board, some circuits on the base board, at least one electric pad and a notch. The electric pad comprises an upper surface plated with at least one layer of anti-oxidant metal foil, a lower surface attached to the base board, a connecting portion connected to the circuit and having a first side surface, a matching portion connected to complementary connector and having a second side surface. The notch is formed on the second side surface of the electric pad and filled with antioxidant.

Other objects, advantages and novel features of the invention will become more apparent from the following detailed description of a preferred embodiment when taken in conjunction with the accompanying drawings.

### BRIEF DESCRIPTION OF THE DRAWINGS

FIG. 1 is a cutaway view illustrating a prefer embodiment of mating portion of an anti-oxidant printed circuit board with goldfingers in according with the present invention.

### DETAILED DESCRIPTION OF THE INVENTION

Reference will now be made in detail to a preferred embodiment of the present invention.

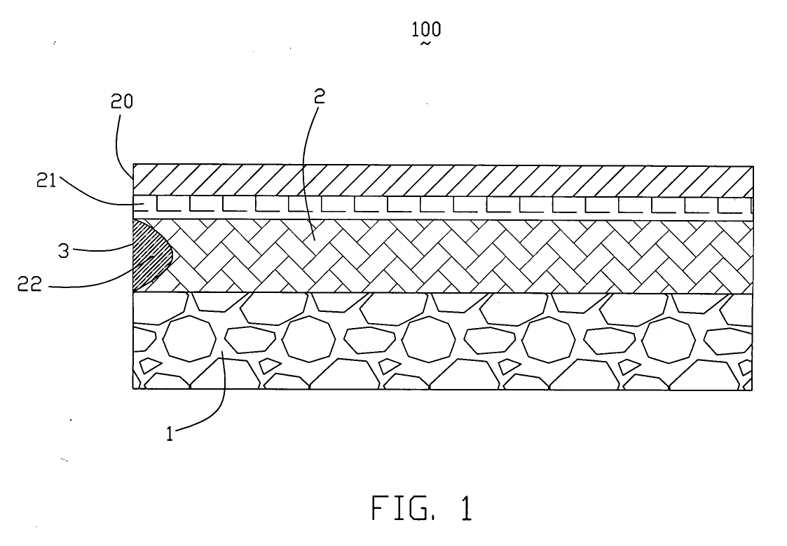

Reference to FIG. 1, an anti-oxidant PCB in according with the best embodiment of the present invention is shown. In this embodiment, the anti-oxidant PCB 100 comprises an insulative base board 1 and some circuits (not shown) on the base board 1. The PCB 100 is a single-layer single-sided board and is made by etching copper foil on a paper phenolic substrate.

The PCB 100 comprises a connecting end (not shown) used to be connected to the complementary connector. The connecting end have copper pad 2 to electric connect the complementary connector to the inner circuit of the PCB 100. For protecting the copper pad 2 form being oxidized and fretted, the copper pad 2 is always plated a layer of nickel 21 and a layer of gold 20. The nickeled and gilt copper pad 2 is called “goldfinger”.

In the electroplate process, each copper pad 2 needs to be connected to a pilot wire. In this embodiment, the pilot wires are soldered on the copper pad 2. After the nickel foil and gold foil are plated on the copper pad 2, the pilot wire would be cut off from the copper pad 2. Thus, the copper on the section 3 is disclosed in air to form a copper area (not shown). In this embodiment, a method of adding antioxidant is used on the PCB 100 to protect the copper area from being oxidized. Firstly, copper area is chemically etched, but the nickel and gold area is not etched. Thus, a notch 22 having proper size is formed on the copper area through controlling the continuing time of etch and the concentration of etch. And then, the notch 22 is filled with some antioxidant which protects the copper from disclosing in air. Accordingly, the copper area on the section is covered by antioxidant but not disclosed in air. In this embodiment, the antioxidant is O.S.P (Organic Solderability Preservatives). In other embodiment, the material filled in the notch can be changed to other antioxidant instead of O.S.P. And the method as above can be used on double-sided PCBs, multi-layers PCBs, FPCs and so on.

While the foregoing description includes details which will enable those skilled in the art to practice the invention, it should be recognized that the description is illustrative in nature and that many modifications and variations thereof will be apparent to those skilled in the art having the benefit of these teachings. It is accordingly intended that the invention herein be defined solely by the claims appended hereto and that the claims be interpreted as broadly as permitted by the prior art.

What is claimed is:

1. An anti-oxidant printed circuit board, comprising:
at least one layer of insulative base board;
some circuits, set on the base board;
at least one electric pad, comprising an upper surface plated with at least one layer of anti-oxidant metal foil, a lower surface attached to the base board, a connecting portion connected to the circuit and having a first side surface, a matching portion connected to complementary connector and having a second side surface;
a notch, formed on the second side surface and filled with antioxidant.

2. The anti-oxidant printed circuit board as claimed in claim 1, wherein said printed circuit board is inflexible.

3. The anti-oxidant printed circuit board as claimed in claim 1, wherein said printed circuit board is flexible.

4. The anti-oxidant printed circuit board as claimed in claim 1, wherein said notch is formed by etching the second side surface of the electric pad.

5. The anti-oxidant printed circuit board as claimed in claim 1, wherein said electric pad is made from copper and said antioxidant metal foil is made from gold.

6. The anti-oxidant printed circuit board as claimed in claim 5, further comprises another layer of anti-oxidant metal foil between the gold foil and the electric pad.

7. The anti-oxidant printed circuit board as claimed in claim 1, wherein said antioxidant is made from electric material.

8. A printed circuit board comprising:
an insulative base board; and
a plurality of circuit pads formed on one surface of the base board, each of said circuit pads defining a copper layer covered by a nickel layer and further by a gold layer successively; wherein
an edge of said copper layer is initially notched and further successively filled with antioxidant material.
